(19) United States
(12) Patent Application Publication
(10) Pub. No.: US 2010/0128445 A1
(43) Pub. Date: May 27, 2010

(54) Clamp for mounting semiconductor laser bar chips and method of mounting chips

(75) Inventor: Bifeng Xiong, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: Shenzhen Century Epitech Photonics Technology Co. Ltd., Shenzhen (CN)

(21) Appl. No.: 12/431,341

(22) Filed: Apr. 28, 2009

(30) Foreign Application Priority Data
Nov. 26, 2008 (CN) 200810217706.8

(51) Int. Cl. H05K 7/20; H05K 7/00

(52) U.S. Cl. 361/717; 361/820

(57) ABSTRACT

A clamp includes a base, a limiting member, a positioning assembly, and a pressing assembly. The base defines a gap. The limiting member defines a limiting slot corresponding to the gap. The positioning assembly is positioned at a first side of the limiting member. The positioning assembly includes a positioning handle and a pushing member. The pushing member extends in the limiting slot, and the positioning handle runs through the limiting member and is connected to the pushing member. The pressing assembly is positioned at a second side opposite to the first side. The pressing assembly runs through the limiting member and extends in the limiting slot. A chip is capable of being pushed to the position of the gap by the pushing member with operating the positioning handle and resists against the pressing assembly, thus being clamped. The present disclosure also provides a mounting method using the clamp.

### CROSS-REFERENCE TO RELATED PATENT APPLICATION

This application claims priority of Chinese Patent Application No. 200810217706.8, filed on Nov. 26, 2008, the disclosure of which is incorporated herein in its entirety by reference.

### FIELD OF THE INVENTION

The present disclosure generally relatives to clamps and methods of mounting chips using the clamps and, particulary, to a clamp for mounting semiconductor laser bar chips and a method of mounting the chips.

### BACKGROUND OF THE INVENTION

In the semiconductor photoelectricity field, manufacturing technology of semiconductor laser bar products is a basis of applying semiconductor larer bar products. Particularly, mounting technology of mounting a semiconductor laser bar chip and a heat sink together is one of the critical technologies. Generally, high power semiconductor laser bar chips are mounted by P-side mounting method. The reason is that the P-side of the chip should be mounted to a heat sink capable of dispersing heat quickly, because the high power semiconductor laser bar chip produces a mount of heat during working and the heat source is closed to the P-side of the chip. As such, the heat sink not only disperses heat, but also acts as a P-electrode. The semiconductor laser bar chip and the heat sink are generally soldered together using a medium of metallic solder metarial, so that heat and electricity can be conducted efficiently therebetween and the semiconductor laser bar chip and the heat sink are firmly connected. A surface, to be contacted with a P-side of the chip, of the heat sink is plated with metallic solder material with the in advance, and then the semiconductor laser bar chip and the heat sink are mounted together by solder. Methods for mounting a N-side of the chips includes various of manners, for example, adopting gold wires as electrodes or a manner similar to the P-side mounting method described above. Using the latter method, i.e., the manner similar to the P-side mounting method, to mounting the N-side can disperse heat efficiently. It can be understood that, to mount the heat sink (also used as P-electrode), the chip, and a N-electrode simultaneity is most difficult.

There are two methods to position and mount the semiconductor laser arry chip and the heat sink together. Referring to FIG. 6, one is adopting a mounting system including a chip position controller 111 configured to adjust a position of a chip 11, a heat sink position controller 121 configured to adjust a position of a heat sink 12, and a high magnification video system 131 having a microscope unit 13. The chip 11 and the heat sink 12 are arranged below the microscope unit 13. The microscope unit 13 scans edges of the chip 11 and the heat sink 12, and the high magnification video system 131 calculates the chip 11 and the heat sink 12 being in desired positions or not. However, precise chip position controller 111 and precise heat sink position controller 121 are needed, thus resulting in a high cost. In addition, a precision of positioning the chip 11 relative to the heat sink 12 is determined by the high magnification video system 131 that has a precision of several microns. Furthermore, a mounting efficiency is low. Referring to FIG. 7, the other one is adopting a mounting system including a chip position controller 211 configured to adjust a position of a chip 21, a heat sink position controller 221 configured to adjust a position of a heat sink 22, and an optical scanning system 231 having a scanning unit 23. The chip 21 and the heat sink 22 are arranged at a side of the scanning unit 23. However, precise chip position controller 211, precise heat sink position controller 221, and expensive optical scanning system 231 are needed, thus resulting in a high cost. In addition, a mounting efficiency is low. To mount the heat sink (also used as P-electrode), the chip, and the N-electrode together simultaneily with the above-described two methods is difficult.

Therefore, a new clamp for mounting semiconductor laser bar chips and a new method of mounting chips are desired to overcome the above-described shortcomings.

### SUMMARY OF THE INVENTION

A clamp for mounting chips comprises a base, a limiting member, a positioning assembly, and a pressing assembly. The base defines a gap. The limiting member is fixed on the base, and defines a limiting slot corresponding to the gap. The limiting member has a first side and a second side opposite to the first side. The positioning assembly is positioned at the first side of the limiting member. The positioning assembly comprises a positioning handle and a pushing member. The pushing member extends in the limiting slot, and the positioning handle runs through the limiting member and is connected to the pushing member. The pressing assembly is positioned at the second side of the limiting member. The pressing assembly runs through the limiting member and extends in the limiting slot. A chip is capable of being pushed to the position of the gap by the pushing member with operating the positioning handle and resists against the pressing assembly, thus being clamped.

A method of mounting chips is provide. A heat sink and a N-electrode are to be mounted on opposite sides of a chip. The chip has a P-side, a N-side, and a light-outgoing surface, the heat sink, the chip. The N-electrode are mounted together by a clamp comprising a base defining a gap, a limiting member defining a limiting slot corresponding to the gap, a pressing assembly, and a positioning assembly. The positioning assembly and the pressing assembly are positioned at opposited sides of the limiting member. The method comprising: (1) the heat sink plated with solder material is put in a limiting slot of the limiting member mounted on the base, and put on a surface of the base, the positioning handle of the positioning assembly is pushed to slide the pushing member, thus pushing the heat sink to a position in range of ¼˜¾ portion of a gap of the base and positioning the heat sink; (2) a clamp is slanted through an angle, so that the pressing assembly is on the top side and a plated surface of the heat sink faces the upside, the chip is put in the limiting slot with the P-side of the chip acing a plated film of the heat sink, the chip slides towards the base due to the gravity of the chip, a light-outgoing portion of the light-outgoing surface of the chip is positioned above the gap, and a portion of the light-outgoing surface of the chip which is adjacent to the N-side of the chip is attached at an edge of the gap, the slanted angle of the clamp is in a range of 30˜60 degrees; (3) with a plated surface facing the N-side of the chip, the N-electrode is put on the base; and (4) the N-electrode is pushed towards the N-side of the chip by pushing the pressing assembly, thus clamping the N-electrode, the chip, and the heat sink resisting the positioning assembly together.

### BRIEF DESCRIPTION OF THE DRAWINGS

The componets in the drawings are not necessarily drawn to scale, the emphasis instead being placed upon illustrating the principles of the present disclosure. Moreover, in the drawings, like reference numerals designate corresponding parts throughout several views, and all the views are schematic.

FIG. 1 is an assembled, isometric view of an embodiment of a clamp for mounting semiconductor laser bar chips of of the present disclosure.

FIG. 2 is an assembled, isometric view showing the clamp of FIG. 1, showing a heat sink, a chip, and a N-electrode put on the clamp.

FIG. 3 is an assembled, isometric view showing the clamp of FIG. 2, showing the heat sink, the chip, and the N-electrode clamped by the clamp.

FIG. 4 is a cross-sectional view of FIG. 3 taken along line IV-IV.

FIG. 5 is a flow chart showing an embodiment of a method for mounting semiconductor laser bar chips of the present disclosure.

FIG. 6 is a first typical mounting system.

FIG. 7 is a second typical mounting system.

### DETAILED DESCRIPTION OF THE INVENTION

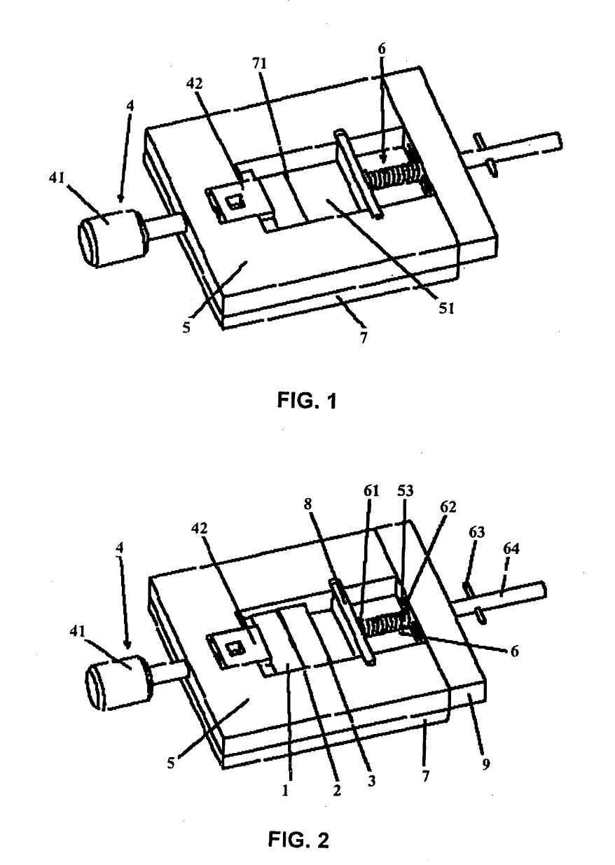

Referring to FIG. 1, an embodiment of a clamp for mounting semiconductor laser bar chips of of the present disclosure is shown. The clamp (not labeled) includes a positioning assembly 4, a limiting member 5, a pressing assembly 6, and a base 7. The clamp is used to mount a heat sink 1, a chip 2, and a N-electrode 3 together. The chip 2 may be a semicondutor laser bar chip. The positioning assembly 4 and the pressing assembly 6 are positioned at opposite ends of the base 7, and the limiting member 5 is located on the base 7.

The base 7 is substantially a sheet including a smooth top surface (not labeled). The base 7 defines a gap 71 with a width corresponding to a thickness of the chip 2 to be mounted. The gap 71 is defined in the top surface. The heat sink 1, the chip 2, and the N-electrode 3 may be precisely aligned to each other when positioned on the base 7, because the top surface of the base 7 is smooth.

The limiting member 5 is positioned on the top surface of the base 7. The limiting member 5 and the base 7 may be fixed by screws or by pasting. The limiting member 5 is substantially a sheet defining a limiting slot 51. The gap 71 of the base 7 corresponds to the limiting slot 51 so that the gap 71 is exposed via the limiting slot 51.

The positioning assembly 4 includes a positioning handle 41 and a pushing member 42 connected to the positioning handle 41. The pushing member 42 extends in the limiting slot 51. Part of the positioning handle 41 runs through the limiting member 5 and connected to the positioning handle 41. The limiting member 5 defines a threaded hole. The positioning handle 41 is a helical screw. The positioning handle 41 runs through and engage with the threaded hole of the limiting member 5, and then being connected to the pushing member 42. The engagement of the positioning handle 41 and the threaded hole of the limiting member 5 makes the positioning assembly 4 can move when the positioning handle 41 is rotated. The pushing member 42 is a pushing block for facilitating to be pushed and has a large contacting area for contacting with the heat sink 1. Part of the positioning handle 41 is outside the limiting member 5 and at least part of the pushing member 42 capable of extending in the limiting slot 51 of the limiting member 5.

The pressing assembly 6 runs through the limiting member 5 and extends in the limiting slot 51. The chip 2 can be pushed to the position of the gap 71 by the pushing member 42 with operating the positioning handle 41 and resists against the pressing assembly 6, thus being clamped.

Referring to FIGS. 2 through 4, the pressing assembly 6 forms a bulgy protrusion 61 at an end of the pressing assembly 6 that protrudes into the limiting slot 51. In use, the protrusion 61 may be configured to resist and press the N electrode 3. The pressing assembly 6 may further include an elastic member 62. In the illustrated embodiment, the elastic member 62 is a compression spring sleeved on the pressing assembly 6. Alternatively, the elastic member 62 may be other components that is changeable in length. The elastic member 62 provides a push force among the heat sink 1, the chip 2, and the N-electrode 3 during a process of eutectics soldering, so that the heat sink 1, the chip 2 and the N-electrode 3 can be mounted together better. The pressing assembly 6 may further include a handspike 64 extending outside the limiting member 5. A limiting pin 63 is mounted on the handspike 64. The limiting member 5 further defines a guiding slot 53. When the handspike 64 is pushed towards the limiting slot 51 of the limiting member 5, the limiting pin 63 is engaged in the guiding slot 53, such that the pressing assembly 6 can not deflect during pressing. Alternatively, the pressing assembly 6 may be connected to the limiting member 5 via a crossbeam 9. That is, the elastic member 62 and the handspike 64 run through the crossbeam 9 before connected to the limiting member 5. The crossbeam 9 may be connected to the limiting member 5 via bolts or screws.

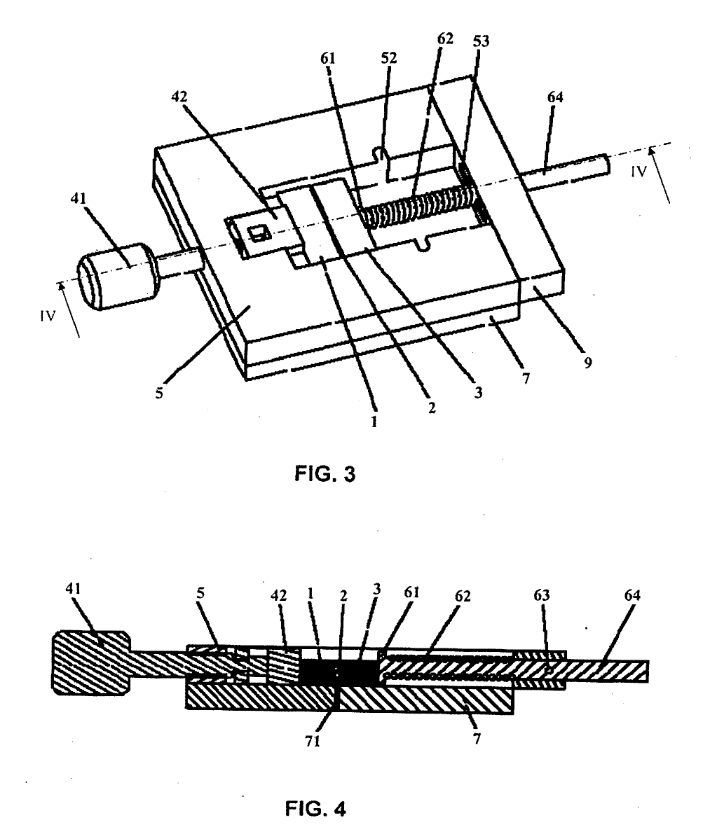

The limiting member 5 defines a pair of engaging slots 52 (see FIG. 3) that are opposite to each other. Opposite ends of a block 8 is positioned in the engaging slots 52, such that the block 8 traverses the limiting slot 51. The protrusion 61 of the pressing assembly 6 is to resist the block 8. Before mounting the heat sink 1, the chip 2 and the N-electrode 3 together, the block 8 resists the pressing assembly 6. After the the heat sink 1, the chip 2 and the N-electrode 3 are put in place, the block 8 is taken away to allow the pressing assembly 6 pressing the heat sink 1, the chip 2, and the N-electrode 3.

In alternative embodiments, the base 7, the limiting member 5, and the crossbeam 9 may be integrally formed to form an integral member. In this case, a bottom portion of the integral member defines the gap 71, and a top portion of the integral member defines the limiting slot 51.

The present disclosure also provides a method of mounting chips. The heat sink 1 and the N-electrode 3 need to be mounted on opposite sides of the chip 2. The chip 2 includes a P-side, a N-side, and a light-outgoing surface. The method includes the following steps.
(1) The heat sink 1 plated with solder material is put in the limiting slot 51 of the limiting member 5 and on the top surface of the base 7. The positioning handle 41 of the positioning assembly 4 is pushed to slide the pushing member 42, thus pushing the heat sink 1 to the one second portion (½) of the gap 71 of the base 7 and positioning the heat sink 1. Alternatively, the heat sink 1 may be pushed to the one fourth to three fourth (¼˜¾) portion of the gap 71;
(2) The clamp is slanted through 45 degrees, so that the pressing assembly 6 is on the top side and a plated surface of the heat sink 1 faces the upside. The chip 2 is put in the limiting slot 51 with the P-side of the chip 2 facing a plated film of the heat sink 1. The chip 2 slides towards the base 7 due to the gravity of the chip 2. A light-outgoing portion of the light-outgoing surface of the chip 2 is positioned above the gap 71, and a portion of the light-outgoing surface of the chip 2 which is adjacent to the N-side of the chip 2 is positioned on the base 7 and at an edge of the gap 71. In alternative embodiment, the clamp may be slanted through 30˜60 degrees;
(3) With a plated surface facing the N-side of the chip 2, the N-electrode 3 is put on the base 7;
(4) The N-electrode 3 is pushed towards the N-side of the chip 2 by pushing the pressing assembly 6, thus clamping the N-electrode 3, the chip 2, and the heat sink 1 resisting the positioning assembly 4 together.

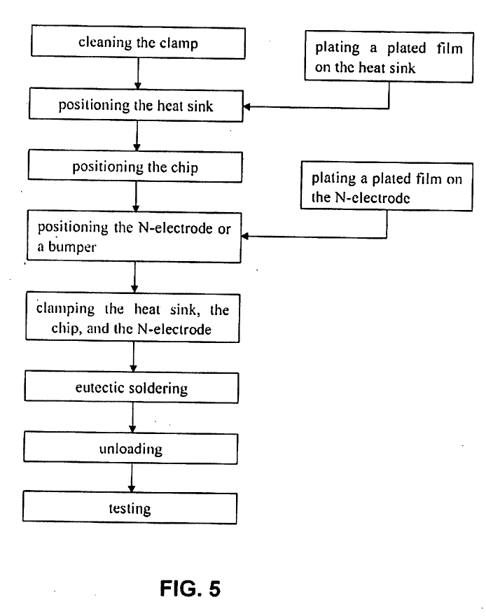

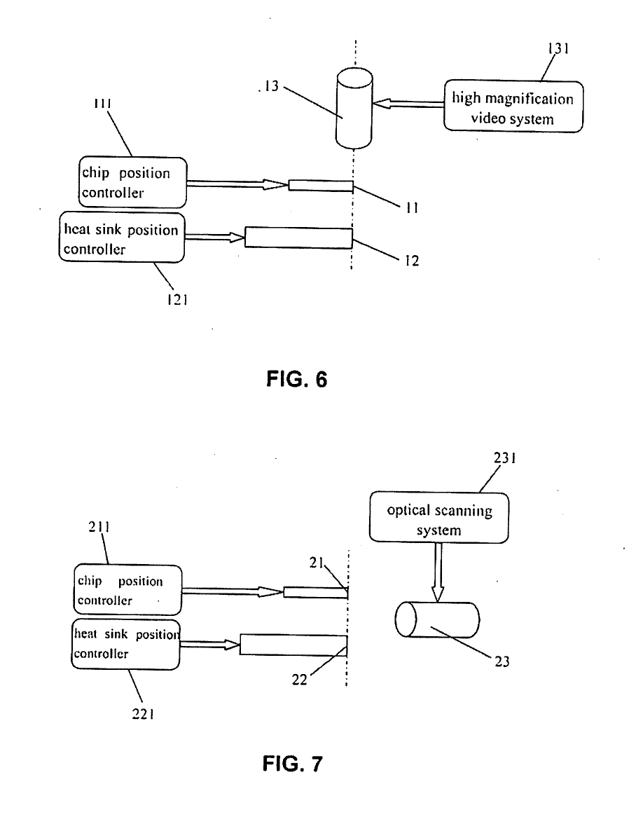

A flow chart of the mounting method is shown in FIG. 5. The flow of the mounting method includes the steps of cleaning the clamp, plating a plated film on the heat sink 1, plating a plated film on the N-electrode 3, positioning the heat sink 1, positioning the chip 2, positioning the N-electrode 3 or a bumper, clamping the heat sink 1, the chip 2, and the N-electrode 3, eutectics soldering, unloading, and testing.

The mounting method and a process of using the clamp are detailed below.

In the step of cleaning the clamp, the clamp is put in an organic solvent such as acetone, isopropylcarbinol, or alcohol, and then cleaned by ultrasonic. After cleaned clean, the clamp is blowed to dry by a nitrogen gun.

In the step of plating a plated film on the heat sink 1, solder material is plated on a surface to be mounted and soldered by sputtering method or evaporating method. In a prefered embodiment, the solder material may be high purity indium. A thickness of the plated film is in a range of 5˜10 microns.

In the step of plating a plated film on the N-electrode 3, solder material is plated on a surface to be mounted and soldered, by sputtering method or evaporating method. If the N-side of the chip 2 not need to be mounted, this step may be omitted. The solder material may be high purity indium, and a thickness of the plated film is in range of 5˜10 microns.

In the step of positioning the heat sink 1, as shown in FIG. 2 and FIG. 3, the heat sink I with the plated film is put on the top surface of the base 7 and stands against a front wall of the pushing member 42. The positioning handle 41 is rotated to push the heat sink 1, thus making a bottom edge of the plated film of the heat sink I to be positioned on the ½ portion (or any portion in a range of ¼˜¾) of the gap 71 of the base 7.

In the step of positioning the chip 2, as shown in FIG. 2 through FIG. 4, the clamp is slanted through 45 degrees (or any angle in a range of 30˜60 degrees) so that the pressing assembly 6 is at the top side and the plated film of the heat sink 1 faces the upside. The chip 2 is lightly put on the plated film of the heat sink 1 by a vacuum absorbing device with the P-side of the chip 2 facing the plated film of the heat sink 1 and the light-outgoing surface facing the underside, i.e., facing the gap 71. The chip 2 slides towards the base 7 for the gravity of the chip 2. The light-outgoing portion of the light-outgoing surface of the chip 2 is positioned above the gap 71, and no gap is between the chip 2 and the top surface of the base 7. Referring to FIG. 4, the light-outgoing portion of the light-outgoing surface of the chip 2 corresponds to the gap 71 without contacting anything, and a part of the light-outgoing surface of the chip 2, which is adjacent to the N-side of the chip 2 is attached at an edge of the gap 71 of the base 7. General chips 2 in the market usually have a thickness in a range of 0.12˜0.15 millimeters, and a distance between a light-outgoing opening and the P-side of the general chips 2 is usually equal to or less than 0.05 millimeters. Therefore, the structure of the clamp and the mounting method can ensure that the light-outgoing portion exactly corresponds to the gap 71 and contacts nothing.

In the step of positioning the N-electrode or the bumper, referring to FIG. 2 through FIG. 4, the N-electrode 3 with plated film is put on the base 7, with the plated surface facing the chip 2. The plated surface of the N-electrode 3 stands against the N-side of the chip 2. The the chip 2 and the N-electrode 3 are perpendicular to the base 7, such that the sidewalls of chip 2 and the N-electrode 3 fully contact with the top surface of the base 7.

In the step of clamping the heat sink 1, the chip 2, and the N-electrode 3, referring to FIG. 3 and FIG. 4, the block 8 is removed to make the protrusion 61 of the pressing assembly 6 resisting the N-electrode 3. In some cases, if the N-electrode 3 not need to be mounted, the N-electrode 3 may be instead by a N-electrode not plated with solder material called as a bumper. A force applied to the heat sink 1, the chip 2, and the N-electrode 3 (or the bumper), which is from the pressing assembly 6, is in a range of 100˜300 grams.

In the step of eutectics soldering, the clamp clamping the heat sink 1, the chip 2, and the N-electrode 3 (or the bumper) is put in a vacuum eutectics soldering oven to be soldered with high temperature. The plated films, i.e., the solder material, of the heat sink 1, and the N-electrode 3 are melted under the high temperature. Then, the plated films consolidate when the temperature is lowered, thus firmly mounting the heat sink 1, the chip 2, and the N-electrode 3. In the process of eutectics soldering, the temperature is preferred to 160˜210 degrees centigrade, and the preferred temperature is kept for more than three minutes. A plurality of clamps may be put in the vacuum eutectics soldering oven and soldered simultaneity, to improve the manufacturing efficiency.

In the step of unloading, the clamp is taken out of the vacuum eutectics soldering oven. The handspike 64 of the pressing assembly 6 is pulled out of the limiting slot 51 and the block 8 is inserted into the engaging slots 52. The front end of the protrusion 61 of the pressing assembly 6 resists the block 8. Thus, the heat sink 1, the chip 2, and the N-electrode 3 may be taken out from the clamp.

In the step of testing, an aspect of the heat sink 1, the chip 2, and the N-electrode 3 mounted together is all-around tested by optical testing, and photoelectric performances of the heat sink 1, the chip 2, and the N-electrode 3 mounted together are tested by compositive testing. As such, the flow for mounting the heat sink 1, the chip 2 and the N-electrode 3 is completed.

Using the clamp and the method of mounting chips of the present disclosure, the heat sink 1, the chip 2 and the N-electrode 3 can be easily mounted together simultaneity, just by rotating the positioning handle 41 to push the pushing member 42. The process is quite simple and has low cost. Mounting the heat sink 1, the chip 2 and the N-electrode 3 together can be performed in mass manufacturing, and a manufacturing efficiency is improved.

Finally, while various embodiments have been described and illustrated, the disclosure is not to be construed as being limited thereto. Various modifications can be made to the embodiments by those skilled in the art without departing from the true spirit and scope of the disclosure as defined by the appended claims.

What is claimed is:

1. A clamp for mounting chips, comprising:
a base defining a gap;
a limiting member fixed on the base, the limiting member defining a limiting slot corresponding to the gap, and the limiting member having a first side and a second side opposite to the first side;
a positioning assembly positioned at the first side of the limiting member, the positioning assembly comprising a positioning handle and a pushing member, the pushing member extending in the limiting slot, and the positioning handle running through the limiting member and connected to the pushing member; and
a pressing assembly positioned at the second side of the limiting member, the pressing assembly running through the limiting member and extending in the limiting slot;
wherein a chip is capable of being pushed to the position of the gap by the pushing member with operating the positioning handle and resists against the pressing assembly, thus being clamped.

2. The clamp as claimed in claim 1, wherein the gap has a width corresponding to a thickness of the chip.

3. The clamp as claimed in claim 2, wherein the base has a smooth surface.

4. The clamp as claimed in claim 3, wherein the pressing assembly comprises a protrusion, and the protrusion is formed at an end of extending in the limiting slot of the limiting member.

5. The clamp as claimed in claim 4, wherein the limiting member defines an engaging slot, the clamp further comprises a block for engaging in the engaging slot, the block traverses the limiting slot, and the protrusion of the pressing assembly is to resist the block.

6. The clamp as claimed in claim 5, wherein the pressing assembly further comprises a handspike extending outside the limiting member, the clamp further comprises a limiting pin mounted on the handspike.

7. The clamp as claimed in claim 6, wherein the limiting member further defines a guiding slot, when the handspike is pushed towards the limiting slot of the limiting member, the limiting pin is engaged in the guiding slot.

8. The clamp as claimed in claim 1, wherein the pressing assembly further comprises an elastic member sleeved on the pressing assembly.

9. The clamp as claimed in claim 8, wherein the elastic member is a compression spring.

10. The clamp as claimed in claim 8, wherein the limiting member defines a threaded hole, the positioning handle is a helical screw, the positioning handle runs through and engage with the threaded hole of the limiting member, and then being connected to the pushing member.

11. A method of mounting chips, a heat sink and a N-electrode are to be mounted on opposite sides of a chip, the chip has a P-side, a N-side, and a light-outgoing surface, the heat sink, the chip, and the N-electrode are mounted together by a clamp comprising a base defining a gap, a limiting member defining a limiting slot corresponding to the gap, a pressing assembly, and a positioning assembly, the positioning assembly and the pressing assembly are positioned at opposited sides of the limiting member, the method comprising:
(1) the heat sink plated with solder material is put in a limiting slot of the limiting member mounted on the base, and put on a surface of the base, the positioning handle of the positioning assembly is pushed to slide the pushing member, thus pushing the heat sink to a porsition in range of ¼˜¾ portion of a gap of the base and positioning the heat sink;
(2) a clamp is slanted through an angle, so that the pressing assembly is on the top side and a plated surface of the heat sink faces the upside, the chip is put in the limiting slot with the P-side of the chip acing a plated film of the heat sink, the chip slides towards the base due to the gravity of the chip, a light-outgoing portion of the light-outgoing surface of the chip is positioned above the gap, and a portion of the light-outgoing surface of the chip which is adjacent to the N-side of the chip is attached at an edge of the gap, the slanted angle of the clamp is in a range of 30˜60 degrees;
(3) with a plated surface facing the N-side of the chip, the N-electrode is put on the base; and
(4) the N-electrode is pushed towards the N-side of the chip by pushing the pressing assembly, thus clamping the N-electrode, the chip, and the heat sink resisting the positioning assembly together.
